(19) United States
(12) Patent Application Publication
(10) Pub. No.: US 2024/0372525 A1
(43) Pub. Date: Nov. 7, 2024

(54) ACOUSTIC WAVE DEVICE AND METHOD FOR MANUFACTURING ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Kazunori INOUE, Nagaokakyo-shi (JP); Naohiro NODAKE, Nagaokakyo-shi (JP)

(21) Appl. No.: 18/777,668

(22) Filed: Jul. 19, 2024

Related U.S. Application Data
(63) Continuation of application No. PCT/JP2023/001755, filed on Jan. 20, 2023.
(60) Provisional application No. 63/301,546, filed on Jan. 21, 2022.

(51) Int. Cl. H03H 9/145; H03H 3/08; H03H 9/02; H03H 9/25

(52) U.S. Cl. CPC H03H 9/145; H03H 3/08; H03H 9/02559; H03H 9/25

(57) ABSTRACT

An acoustic wave device includes a support substrate including a support and an intermediate layer on the support, a piezoelectric body layer on the intermediate layer, and a functional electrode on the piezoelectric body layer. The piezoelectric body layer includes a through-hole extending through the piezoelectric body layer in a lamination direction of the support, the intermediate layer, and the piezoelectric body layer. The support substrate includes a space portion at a position overlapping a portion of the functional electrode in the lamination direction, and a recess at a position in the space portion at least partially overlapping the through-hole in the lamination direction, the recess being recessed in a direction separating from the piezoelectric body layer.

### CROSS REFERENCE TO RELATED APPLICATIONS

This application claims the benefit of priority to Provisional Application No. 63/301, 546 filed on Jan. 21, 2022 and is a Continuation Application of PCT Application No. PCT/JP2023/001755 filed on Jan. 20, 2023. The entire contents of each application are hereby incorporated herein by reference.

### BACKGROUND OF THE INVENTION

### 1. Field of the Invention

The present disclosure relates to acoustic wave devices each including a piezoelectric layer (piezoelectric body layer) and methods for manufacturing acoustic wave devices.

### 2. Description of the Related Art

For example, Japanese Unexamined Patent Application Publication No. 2012-257019 discloses an acoustic wave device that uses plate waves. The acoustic wave device described in Japanese Unexamined Patent Application Publication No. 2012-257019 includes a support, a piezoelectric substrate, and an IDT electrode. The support has a space portion. The piezoelectric substrate is provided on the support so as to overlap the space portion. The IDT electrode is provided on the piezoelectric substrate so as to overlap the space portion. In the acoustic wave device, a plate wave is excited by the IDT electrode. An end edge portion of the space portion does not include a linear portion extending parallel to the propagation direction of the plate wave excited by the IDT electrode.

### SUMMARY OF THE INVENTION

There has recently been a demand for an acoustic wave device capable of reducing or preventing cracks in an intermediate layer of a support while reducing the manufacturing cost.

Example embodiments of the present invention provide acoustic wave devices and manufacturing methods thereof each capable of reducing or preventing cracks in an intermediate layer of a support while reducing the manufacturing cost.

An acoustic wave device according to an example embodiment of the present disclosure includes?.

A method for manufacturing an acoustic wave device according to another example embodiment of the present disclosure is a method for manufacturing an acoustic wave device including a support substrate including a support and an intermediate layer on the support, a piezoelectric body layer on the intermediate layer, and a functional electrode on the piezoelectric body layer, in which the piezoelectric body layer includes a through-hole extending through the piezoelectric body layer in a lamination direction of the support, the intermediate layer, and the piezoelectric body layer, and the support substrate includes a space portion at a position overlapping a portion of the functional electrode in the lamination direction, and a recess at a position at least partially overlapping the through-hole in the lamination direction, the recess being recessed in a direction separating from the piezoelectric body layer from the space portion, the method including forming the through-hole so as to extend through a sacrificial layer surrounded by the piezoelectric body layer and the support substrate in the lamination direction, and removing the sacrificial layer through the through-hole to form the space portion.

Example embodiments of the present disclosure provide acoustic wave devices and manufacturing methods thereof each capable of reducing or preventing cracks in an intermediate layer of a support while reducing the manufacturing cost.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an appearance of an acoustic wave device according to first and second aspects of example embodiments of the present disclosure.

FIG. 1B is a plan view illustrating an electrode structure on a piezoelectric layer.

FIG. 2 is a sectional view of a portion taken along line A-A in FIG. 1A.

FIG. 3A is a schematic elevational sectional view for explaining a Lamb wave propagating through a piezoelectric film of an acoustic wave device of the related art.

FIG. 3B is a schematic elevational sectional view for explaining waves of an acoustic wave device according to an example embodiment of the present disclosure.

FIG. 4 is a schematic diagram illustrating a bulk wave when a voltage is applied between a first electrode and a second electrode such that the second electrode has a higher potential than the first electrode.

FIG. 5 is a graph illustrating resonance characteristics of an acoustic wave device according to an example embodiment of the present disclosure.

FIG. 6 is a graph illustrating the relationship between d/2p and a fractional bandwidth of a resonator in the acoustic wave device.

FIG. 7 is a plan view of another acoustic wave device according to an example embodiment of the present invention.

FIG. 8 is a reference diagram illustrating an example of the resonance characteristics of the acoustic wave device.

FIG. 9 is a graph illustrating the relationship between a fractional bandwidth and a phase rotation amount of a spurious impedance normalized by 180 degrees as a magnitude of spurious when a large number of acoustic wave resonators are configured.

FIG. 10 is a graph illustrating the relationship among d/2p, a metallization ratio MR, and a fractional bandwidth.

FIG. 11 is a graph illustrating a map of the fractional bandwidth with respect to Euler angles (0°, θ, ψ) of LiNbO₃ when d/p is infinitely close to 0.

FIG. 12 is a partially cutaway perspective view for explaining an acoustic wave device according to an example embodiment of the present invention.

FIG. 13 is a plan view illustrating an example of an acoustic wave device according to an example embodiment of the present invention.

FIG. 14 is a sectional view taken along line XIV-XIV in FIG. 13.

FIG. 15 is a first diagram for explaining an example of a method for manufacturing the acoustic wave device in FIG. 13.

FIG. 16 is a second diagram for explaining an example of a method for manufacturing the acoustic wave device in FIG. 13.

FIG. 17 is a third diagram for explaining an example of a method for manufacturing the acoustic wave device in FIG. 13.

FIG. 18 is a fourth diagram for explaining an example of a method for manufacturing the acoustic wave device in FIG. 13.

FIG. 19 is a fifth diagram for explaining an example of a method for manufacturing the acoustic wave device in FIG. 13.

FIG. 20 is a sectional view illustrating a first modification of the acoustic wave device in FIG. 13.

FIG. 21 is a sectional view illustrating a second modification of the acoustic wave device in FIG. 13.

FIG. 22 is a partial sectional view of an acoustic wave device without a recess.

### DETAILED DESCRIPTION OF THE EXAMPLE EMBODIMENTS

Hereinafter, example embodiments of the present disclosure will be described with reference to the accompanying drawings. The following description is merely exemplary in nature and is not intended to limit the present disclosure, the applications of example embodiments of the present disclosure, or the use of example embodiments of the present disclosure. The drawings are schematic, and dimensional ratios and the like do not necessarily correspond to the actual ones.

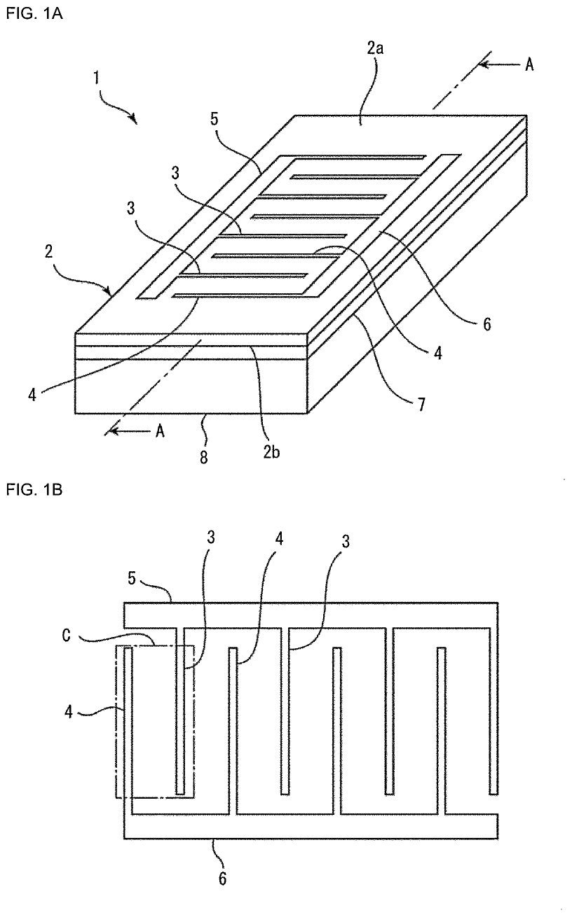

With reference to FIGS. 1A to 12, acoustic wave devices according to first to fourth aspects on which example embodiments of the present disclosure are based will be described.

An acoustic wave device according to the first, second, and third aspects of example embodiments of the present disclosure of the present disclosure include a piezoelectric layer made of lithium niobate or lithium tantalate, for example, and a first electrode and a second electrode facing each other in a direction intersecting the thickness direction of the piezoelectric layer.

An acoustic wave device according to the first aspect of example embodiments of the present disclosure uses a bulk wave in a first-order thickness-shear mode.

In an acoustic wave device according to the second aspect of example embodiments of the present disclosure, the first electrode and the second electrode are adjacent to each other, and d/p is less than or equal to about 0.5, for example, where d is the thickness of the piezoelectric layer, and p is the center-to-center distance between the first electrode and the second electrode. With this configuration, in the first and second aspects, a Q factor can be increased even when the size of the acoustic wave device is reduced.

An acoustic wave device according to the third aspect of example embodiments of the present disclosure uses a Lamb wave as a plate wave. The Lamb wave can provide resonance characteristics.

An acoustic wave device according to the fourth aspect of example embodiments of the present disclosure includes a piezoelectric layer made of lithium niobate or lithium tantalate, and an upper electrode and a lower electrode facing each other in the thickness direction of the piezoelectric layer with the piezoelectric layer interposed therebetween, and uses a bulk wave.

The present disclosure will be clarified by describing specific example embodiments of the acoustic wave devices according to the first to fourth aspects below with reference to the drawings.

It should be noted that each example embodiment described in this specification is illustrative, and partial substitution or combination of configurations described in different example embodiments is possible.

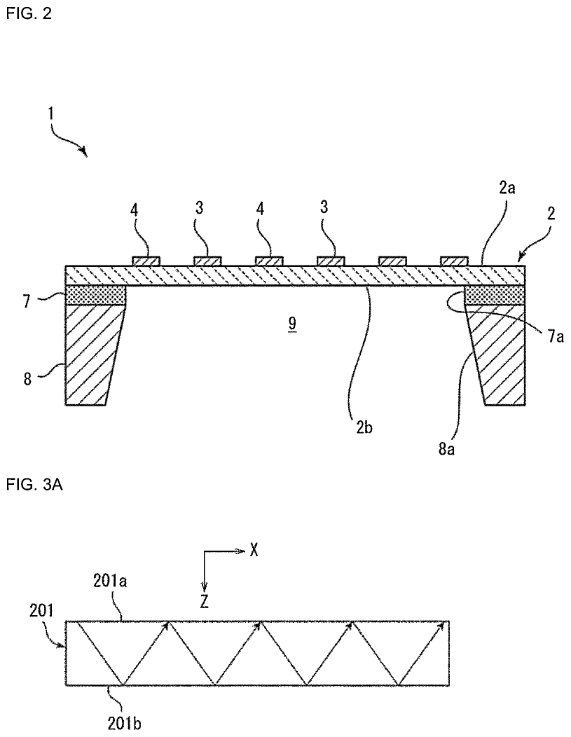

FIG. 1A is a schematic perspective view illustrating an appearance of an acoustic wave device according to an example embodiment of the first and second aspects of example embodiments of the present disclosure. FIG. 1B is a plan view illustrating an electrode structure on a piezoelectric layer. FIG. 2 is a sectional view of a portion taken along line A-A in FIG. 1A.

An acoustic wave device 1 includes a piezoelectric layer 2 made of LiNbO₃. The piezoelectric layer 2 may be made of LiTaO₃. The cut-angle of LiNbO₃ or LiTaO₃ is a Z-cut in this example embodiment, but may be a rotated Y-cut or X-cut. The propagation directions of Y propagation and X propagation about ±30° are preferable, for example. The thickness of the piezoelectric layer 2 is not particularly limited, but is preferably more than or equal to about 50 nm and less than or equal to about 1000 nm in order to effectively excite the first-order thickness-shear mode, for example.

The piezoelectric layer 2 includes a first main surface 2a and a second main surface 2b facing each other. An electrode 3 and an electrode 4 are provided on the first main surface 2a. Here, the electrode 3 is an example of a “first electrode” and the electrode 4 is an example of a “second electrode”. In FIGS. 1A and 1B, a plurality of electrodes 3 are a plurality of “first electrode fingers” connected to a first busbar 5. A plurality of electrodes 4 are a plurality of “second electrode fingers” connected to a second busbar 6. The plurality of electrodes 3 and the plurality of electrodes 4 are interdigitated with each other.

The electrode 3 and the electrode 4 each have a rectangular or substantially rectangular shape and have a length direction. In a direction orthogonal to the length direction, the electrode 3 and the electrode 4 adjacent thereto face each other. An interdigital transducer (IDT) electrode is thus formed, including the plurality of electrodes 3 and 4, the first busbar 5, and the second busbar 6. The length direction of the electrodes 3 and 4 and the direction orthogonal to the length direction of the electrodes 3 and 4 each are a direction intersecting a thickness direction of the piezoelectric layer 2. Therefore, it can also be said that the electrode 3 and the electrode 4 adjacent thereto face each other in a direction intersecting the thickness direction of the piezoelectric layer 2.

Further, the length direction of the electrodes 3 and 4 may be replaced with the direction orthogonal to the length direction of the electrodes 3 and 4 illustrated in FIGS. 1A and 1B. That is, the electrodes 3 and 4 may extend in the direction in which the first busbar 5 and the second busbar 6 extend in FIGS. 1A and 1B. In this case, the first busbar 5 and the second busbar 6 extend in the direction in which the electrodes 3 and 4 extend in FIGS. 1A and 1B.

A plurality of pairs of structures in which the electrode 3 connected to one potential and the electrode 4 connected to the other potential are adjacent to each other are provided in the direction orthogonal to the length direction of the electrodes 3 and 4 described above. Here, the electrode 3 and the electrode 4 being adjacent to each other refers not to a case where the electrode 3 and the electrode 4 are arranged so as to be in direct contact with each other but to a case where the electrode 3 and the electrode 4 are arranged with an interval therebetween.

In addition, when the electrode 3 and the electrode 4 are adjacent to each other, an electrode connected to a hot electrode or a ground electrode, including the other electrodes 3 and 4, is not arranged between the electrode 3 and the electrode 4. The number of pairs need not be integer pairs, but may be 1.5 pairs, 2.5 pairs, or the like. The center-to-center distance between the electrodes 3 and 4, that is, the pitch is preferably in the range of more than or equal to about 1 μm and less than or equal to about 10 μm, for example. In addition, the center-to-center distance between the electrodes 3 and 4 is a distance connecting the center of the width dimension of the electrode 3 in the direction orthogonal to the length direction of the electrode 3 and the center of the width dimension of the electrode 4 in the direction orthogonal to the length direction of the electrode 4. Further, in a case where at least one of the electrodes 3 and 4 includes a plurality of electrodes (when the electrodes 3 and 4 define a pair of electrodes and there are 1.5 or more pairs of electrodes), the center-to-center distance between the electrodes 3 and 4 refers to the average value of the center-to-center distances between the respective adjacent electrodes 3 and 4 of the 1.5 or more pairs of electrodes 3 and 4. In addition, the width of the electrodes 3 and 4, that is, the dimension of the electrodes 3 and 4 in their facing direction, is preferably in the range of more than or equal to about 150 nm and less than or equal to about 1000 nm, for example. The center-to-center distance between the electrodes 3 and 4 is a distance connecting the center of the dimension (width dimension) of the electrode 3 in the direction orthogonal to the length direction of the electrode 3 and the center of the dimension (width dimension) of the electrode 4 in the direction orthogonal to the length direction of the electrode 4.

In this example embodiment, since the Z-cut piezoelectric layer is used, the direction orthogonal to the length direction of the electrodes 3 and 4 is a direction orthogonal to the polarization direction of the piezoelectric layer 2. This does not apply when a piezoelectric body of another cut-angle is used as the piezoelectric layer 2. Here, “orthogonal” is not limited to strictly orthogonal but may be substantially orthogonal (an angle between the direction orthogonal to the length direction of the electrodes 3 and 4 and the polarization direction is, for example, approximately 90°±10°).

A support 8 is laminated on the second main surface 2b side of the piezoelectric layer 2 with an insulating layer 7 interposed therebetween. The insulating layer 7 and the support 8 have a frame shape and include cavities 7a and 8a as illustrated in FIG. 2. A space portion 9 is thus provided. The space portion 9 is provided so as not to interfere with the vibration of an excitation region C of the piezoelectric layer 2. Therefore, the support 8 is laminated on the second main surface 2b with the insulating layer 7 interposed therebetween at a position not overlapping a portion where at least a pair of electrodes 3 and 4 are provided. Note that the insulating layer 7 need not be provided. Therefore, the support 8 can be directly or indirectly laminated on the second main surface 2b of the piezoelectric layer 2.

The insulating layer 7 is made of silicon oxide. However, the insulating layer 7 can be made of an appropriate insulating material such as silicon oxynitride or alumina in addition to silicon oxide. The support 8 is made of Si. The plane orientation of the surface of Si on the piezoelectric layer 2 side may be (100), (110), or (111). Preferably, high-resistance Si having a resistivity of more than or equal to about 4 kΩ is desirable, for example. However, the support 8 can also be made using an appropriate insulating material or semiconductor material. Examples of the material of the support 8 include piezoelectric bodies such as aluminum oxide, lithium tantalate, lithium niobate, or quartz crystal, various ceramics such as alumina, magnesia, sapphire, silicon nitride, aluminum nitride, silicon carbide, zirconia, cordierite, mullite, steatite, or forsterite, dielectrics such as diamond or glass, semiconductors such as gallium nitride, or the like.

The plurality of electrodes 3 and 4 and the first and second busbars 5 and 6 are made of an appropriate metal or alloy such as Al or an AlCu alloy. In this example embodiment, the electrodes 3 and 4 and the first and second busbars 5 and 6 have a structure in which an Al film is laminated on a Ti film. A material other than the Ti film may be used for an adhesion layer.

At the time of driving, an AC voltage is applied between the plurality of electrodes 3 and the plurality of electrodes 4. More specifically, an AC voltage is applied between the first busbar 5 and the second busbar 6. This makes it possible to obtain resonance characteristics using a bulk wave in the first-order thickness-shear mode excited in the piezoelectric layer 2.

In the acoustic wave device 1, d/p is less than or equal to about 0.5, for example, where d is the thickness of the piezoelectric layer 2, and p is the center-to-center distance between any adjacent electrodes 3 and 4 of the plurality of pairs of electrodes 3 and 4. Therefore, the bulk wave in the first-order thickness-shear mode is effectively excited, and good resonance characteristics can be obtained. More preferably, d/p is less than or equal to about 0.24, for example, in which case even better resonance characteristics can be obtained.

In a case where at least one of the electrodes 3 and 4 includes a plurality of electrodes as in this example embodiment, that is, in a case where the electrodes 3 and 4 define a pair of electrodes and there are 1.5 or more pairs of the electrodes 3 and 4, the center-to-center distance p between the adjacent electrodes 3 and 4 is an average distance of the center-to-center distances between the respective adjacent electrodes 3 and 4.

Since the acoustic wave device 1 according to this example embodiment has the configuration described above, a Q factor is less likely to be reduced even when the number of pairs of the electrodes 3 and 4 is reduced in an attempt to achieve a reduction in size. This is because the resonator does not require reflectors on both sides and has a small propagation loss. In addition, the reason why the above reflector is not required is that the bulk wave in the first-order thickness-shear mode is used.

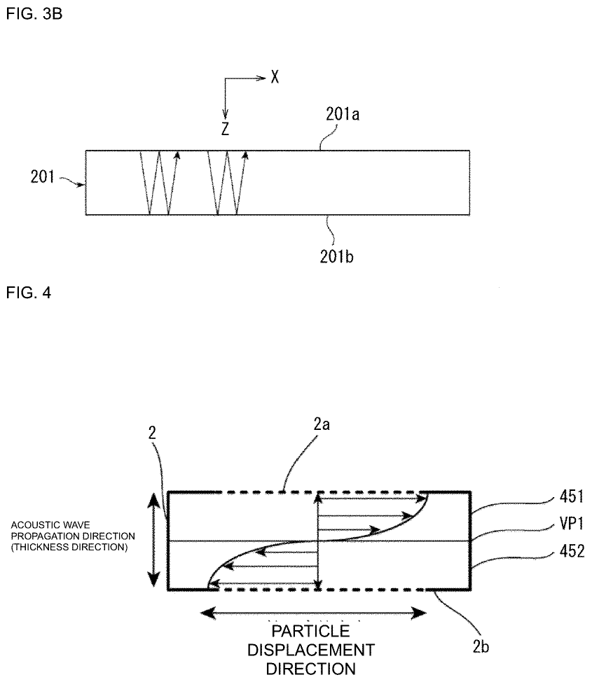

With reference to FIGS. 3A and 3B, description will be given of the difference between a Lamb wave used in an acoustic wave device of the related art and the bulk wave in the first-order thickness-shear mode described above.

FIG. 3A is a schematic elevational sectional view for explaining a Lamb wave propagating through a piezoelectric film in the acoustic wave device of the related art. The acoustic wave device of the related art is described in Japanese Unexamined Patent Application Publication No. 2012-257019, for example. As illustrated in FIG. 3A, in the acoustic wave device of the related art, a wave propagates through a piezoelectric film 201 as indicated by arrows. Here, a first main surface 201a and a second main surface 201b of the piezoelectric film 201 face each other, and a thickness direction connecting the first main surface 201a and the second main surface 201b is a Z direction. An X direction is a direction in which electrode fingers of an IDT electrode are arranged. As illustrated in FIG. 3A, the Lamb wave propagates in the X direction. Although the piezoelectric film 201 vibrates as a whole because of the plate wave, since the wave propagates in the X direction, reflectors are arranged on both sides to obtain resonance characteristics. Therefore, a propagation loss of waves occurs, and the Q factor decreases when the size is reduced, that is, when the number of pairs of electrode fingers is reduced.

On the other hand, as illustrated in FIG. 3B, in the acoustic wave device 1 of this example embodiment, since the vibration displacement is in the thickness-shear direction, the wave substantially propagates in the direction connecting the first main surface 2a and the second main surface 2b of the piezoelectric layer 2, that is, the Z direction, and resonates. Specifically, the direction component of the wave is X significantly than the Z direction component. Since resonance characteristics are obtained by the propagation of the wave in the Z direction, a reflector is not required. Therefore, propagation loss when the wave propagates to the reflector does not occur. Therefore, even when the number of pairs of electrodes including the electrodes 3 and 4 is reduced in an attempt to reduce the size, the Q factor is less likely to be reduced.

As illustrated in FIG. 4, the amplitude direction of the bulk wave in the first-order thickness-shear mode in a first region 451 included in the excitation region C of the piezoelectric layer 2 is opposite the amplitude direction thereof in a second region 452 included in the excitation region C. FIG. 4 schematically illustrates a bulk wave when a voltage is applied between the electrode 3 and the electrode 4 so that the electrode 4 has a higher potential than the electrode 3. The first region 451 is a region between the first main surface 2a and a virtual plane VP1 that is orthogonal to the thickness direction of the piezoelectric layer 2 and divides the piezoelectric layer 2 into two parts in the excitation region C. The second region 452 is a region between the virtual plane VP1 and the second main surface 2b in the excitation region C.

As described above, in the acoustic wave device 1, at least a pair of electrodes including the electrode 3 and the electrode 4 are arranged. Since waves are not propagated in the X direction, the plurality of pairs of electrodes including the electrodes 3 and 4 are not always necessary. That is, only at least a pair of electrodes may be provided.

For example, the electrode 3 is an electrode connected to the hot potential, and the electrode 4 is an electrode connected to the ground potential. However, the electrode 3 may be connected to the ground potential and the electrode 4 may be connected to the hot potential. In this example embodiment, as described above, at least a pair of electrodes are the electrode connected to the hot potential or the electrode connected to the ground potential, and a floating electrode is not provided.

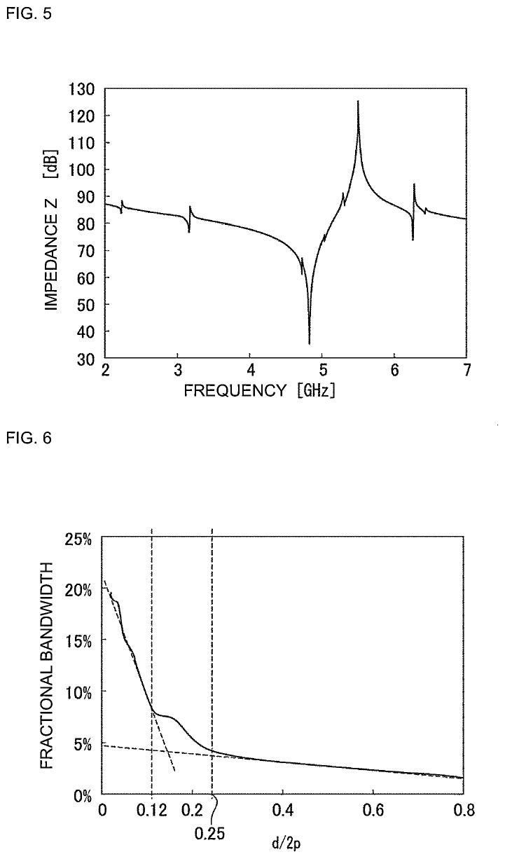

FIG. 5 graph is a illustrating the resonance characteristics of the acoustic wave device according to an example embodiment of the present disclosure. The example design parameters of the acoustic wave device 1 having the resonance characteristics are as follows.
Piezoelectric layer 2: LiNbO₃ with Euler angles (0°, 0°, 90°)
Thickness: 400 nm
Length of region where electrodes 3 and 4 overlap as seen in a direction orthogonal to length direction of electrodes 3 and 4, that is, excitation region C: 40 μm
Number of pairs of electrodes including electrodes 3 and 4: 21 pairs
Center-to-center distance between electrodes: 3 μm
Width of electrodes 3 and 4: 500 nm
d/p: 0.133
Insulating layer 7: silicon oxide film with thickness of 1 μm
Support 8: Si

The length of the excitation region C is a dimension of the excitation region C in the length direction of the electrodes 3 and 4.

In this example embodiment, the electrode-to-electrode distances of the electrode pairs including the electrodes 3 and 4 are all equal in the plurality of pairs. That is, the electrodes 3 and the electrodes 4 are arranged with equal pitches.

As is clear from FIG. 5, good resonance characteristics with the fractional bandwidth of about 12.5% are obtained even though no reflector is provided, for example.

As described above, in this example embodiment, d/p is less than or equal to about 0.5, more preferably less than or equal to about 0.24, for example, where d is the thickness of the piezoelectric layer 2 and p is the center-to-center distance between the electrode 3 and the electrode 4. This will be described with reference to FIG. 6.

A plurality of acoustic wave devices are obtained in the same manner as the acoustic wave device having the resonance characteristics illustrated in FIG. 5, except that d/2p is changed. FIG. 6 is a graph illustrating the relationship between d/2p and a fractional bandwidth of a resonator in the acoustic wave device.

As illustrated in FIG. 6, when d/2p exceeds about 0.25, that is, d/p>about 0.5, the fractional bandwidth is less than about 5% even when d/p is adjusted, for example. On the other hand, when d/2p≤about 0.25, that is, d/p≤about 0.5, the fractional bandwidth can be more than or equal to about 5% by changing d/p within the range, that is, the resonator having a high coupling coefficient can be provided, for example. When d/2p is less than or equal to about 0.12, that is, d/p is less than or equal to about 0.24, the fractional bandwidth can be increased to more than or equal to about 78, for example. In addition, when d/p is adjusted within this range, a resonator having a wider fractional bandwidth can be obtained, and a resonator having a higher coupling coefficient can be realized. Therefore, as in the case of the acoustic wave device according to the second aspect of example embodiments of the present disclosure, it is understood that by setting d/p to less than or equal to about 0.5, for example, a resonator having a high coupling coefficient using the bulk wave in the first-order thickness-shear mode described above can be provided.

Note that, as described above, the at least one pair of electrodes may be a pair of electrodes, and in the case of one pair of electrodes, p is the center-to-center distance between the adjacent electrodes 3 and 4. Further, in the case of 1.5 or more pairs of electrodes, p may be the average distance of the center-to-center distances between the adjacent electrodes 3 and 4.

When the piezoelectric layer 2 has variations in thickness d, a value obtained by averaging the thicknesses may be used.

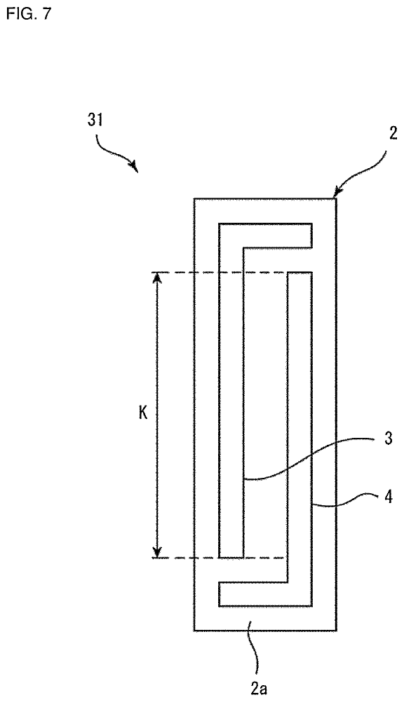

FIG. 7 is a plan view of another acoustic wave device according to an example embodiment of the present disclosure. In an acoustic wave device 31, a pair of electrodes including the electrode 3 and the electrode 4 are provided on the first main surface 2a of the piezoelectric layer 2. K in FIG. 7 is an intersecting width. As described above, in the acoustic wave device 31 of the present disclosure, the number of pairs of electrodes may be one. Also in this case, when d/p is less than or equal to about 0.5, for example, the bulk wave in the first-order thickness-shear mode can be effectively excited.

In the acoustic wave device 1, preferably, it is desirable that the metallization ratio MR of any adjacent electrodes 3 and 4 of the plurality of electrodes 3 and 4 with respect to the excitation region C, which is a region where the adjacent electrodes 3 and 4 overlap as seen in their facing direction, satisfies MR≤about 1.75 (d/p)+0.075, for example. In other words, a region where the plurality of first electrode fingers and the plurality of second electrode fingers overlap as seen in a direction in which the adjacent first electrode fingers and second electrode fingers face each other is an excitation region (intersection region), and it is preferable that MR≤about 1.75 (d/p)+0.075 is satisfied, for example, where MR is the metallization ratio of the plurality of first electrode fingers and the plurality of second electrode fingers to the excitation region. In that case, it is possible to effectively reduce spurious.

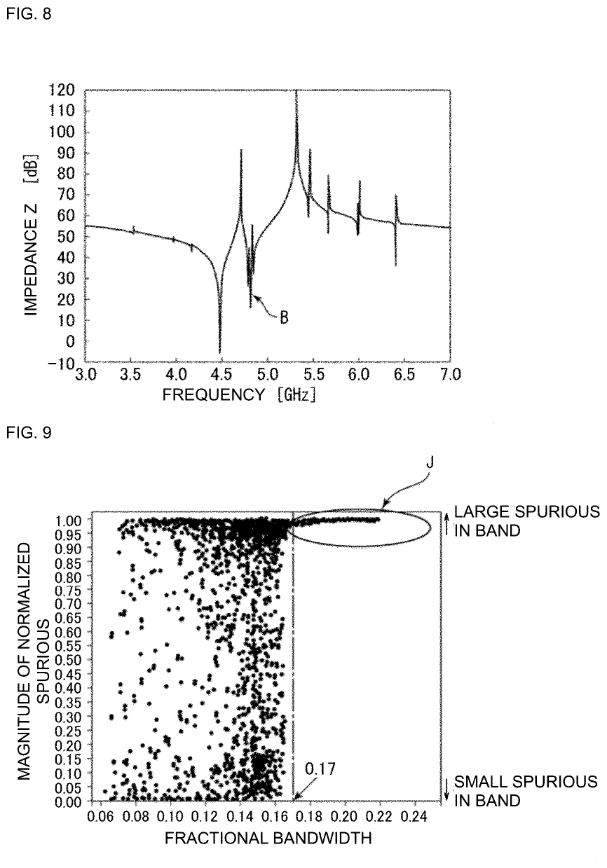

This will be described with reference to FIGS. 8 and 9. FIG. 8 is a reference diagram illustrating an example of the resonance characteristics of the acoustic wave device 1 described above. A spurious indicated by an arrow B appears between a resonant frequency and an anti-resonant frequency. Note that d/p=about 0.08 and the Euler angles of LiNbO₃ are approximately (0°, 0°, 90°), for example. The metallization ratio MR is about 0.35, for example.

The metallization ratio MR will be described with reference to FIG. 1B. In the electrode structure of FIG. 1B, when a pair of electrodes 3 and 4 are focused on, it is assumed that only the pair of electrodes 3 and 4 are provided. In this case, a portion surrounded by a dashed-dotted line is the excitation region C. When the electrode 3 and the electrode 4 are viewed in the direction orthogonal to the length direction of the electrodes 3 and 4, that is, viewed in their facing direction, the excitation region is a region of the electrode 3 that overlaps the electrode 4, a region of the electrode 4 that overlaps the electrode 3, and a region between the electrode 3 and the electrode 4 where the electrode 3 and the electrode 4 overlap each other. An area of the electrodes 3 and 4 in the excitation region C with respect to the area of the excitation region is the metallization ratio MR. That is, the metallization ratio MR is the ratio of the area of the metallization portion to the area of the excitation region.

When a plurality of pairs of electrodes are provided, the ratio of the metallization portion included in the entire excitation region to the total area of the excitation region may be MR.

FIG. 9 is a graph illustrating a relationship between a fractional bandwidth and a phase rotation amount of spurious impedance normalized by 180 degrees as the magnitude of the spurious when a large number of acoustic wave resonators are configured according to this example embodiment. The fractional bandwidth is adjusted by changing the film thickness of the piezoelectric layer and the dimensions of the electrodes. FIG. 9 illustrates the results when a Z-cut LiNbO₃ piezoelectric layer is used, but the same tendency is obtained also when piezoelectric layers with other cut-angles are used.

In a region surrounded by an ellipse J in FIG. 9, the spurious is as large as about 1.0, for example. As is clear from FIG. 9, when the fractional bandwidth exceeds about 0.17, that is, exceeds about 17%, for example, a large spurious with a spurious level of more than or equal to 1 appears in a pass band even when the parameters defining the fractional bandwidth are changed. That is, as in the resonance characteristics illustrated in FIG. 8, a large spurious indicated by the arrow B appears within the band. Therefore, the fractional bandwidth is preferably less than or equal to about 17%, for example. In this case, the spurious can be reduced by adjusting the film thickness of the piezoelectric layer 2, the dimensions of the electrodes 3 and 4, or the like.

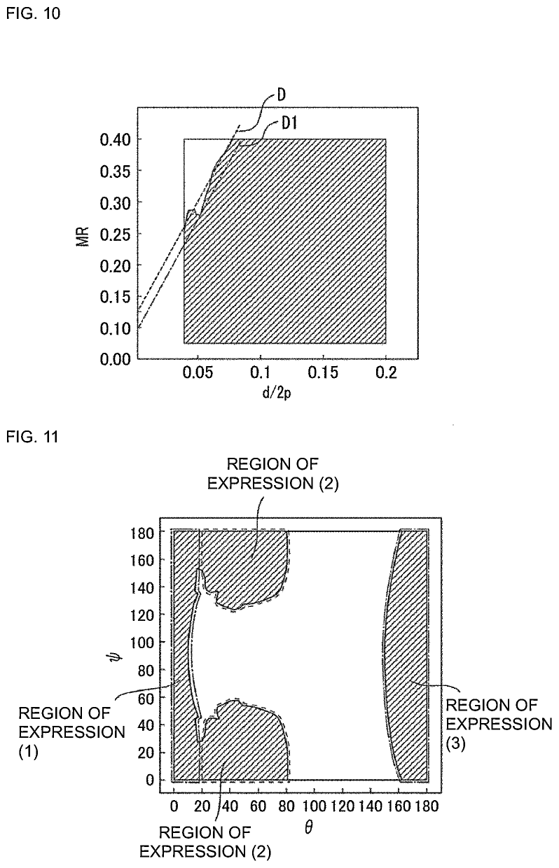

FIG. 10 is a graph illustrating a relationship among d/2p, the metallization ratio MR, and the fractional bandwidth. In the acoustic wave device described above, various acoustic wave devices having different values of d/2p and different values of MR are provided, and the fractional bandwidth is measured. A hatched portion to the right of a dashed line D illustrated in FIG. 10 is a region where the fractional bandwidth is less than or equal to about 17%, for example. The boundary between the hatched region and the non-hatched region is represented by MR=about 3.5 (d/2p)+0.075, for example. That is, MR=about 1.75(d/p)+0.075, for example. Therefore, MR≤about 1.75(d/p)+0.075 is preferably satisfied, for example. In this case, the fractional bandwidth is more likely to be less than or equal to about 17%, for example. More preferably, it is the region in FIG. 10 to the right of a dashed-dotted line D1 indicating MR=about 3.5 (d/2p) +0.05, for example. That is, when MR≤about 1.75 (d/p) +0.05, for example, the fractional bandwidth can be reliably set to less than or equal to about 17%, for example.

FIG. 11 is a graph illustrating a map of the fractional bandwidth with respect to the Euler angles (0°, θ, ψ) of LiNbO₃ when d/p is infinitely close to 0. A hatched portion in FIG. 11 is a region where the fractional bandwidth of at least more than or equal to about 5% is obtained, for example, and the range of the region is approximated by Expression (1), Expression (2), and Expression (3) below.

(0°±10°, 0° to 20°, any ψ) Expression (1)

(0°±10°, 20° to 80°, 0° to 60° (1−(θ−50)²/900)^{1/2}) or (0°±10°, 20° to 80°, [180°−60°(1−(θ−50)²/900)^{1/2]} to 180°) Expression (2)

(0°±10°, [180°−30°(1−(ψ−90)²/8100)^{1/2]} to 180°, any ψ) Expression (3)

Therefore, in the case of the Euler angle range of Expression (1), Expression (2), or Expression (3), the fractional bandwidth can be sufficiently widened, which is preferable.

FIG. 12 is a partially cutaway perspective view for explaining an acoustic wave device according to an example embodiment of the present disclosure. An acoustic wave device 81 includes a support substrate 82. The support substrate 82 includes a recess in its upper surface. A piezoelectric layer 83 is laminated on the support substrate 82. This defines a space portion 9. An IDT electrode 84 is provided on the piezoelectric layer 83 above the space portion 9. Reflectors 85 and 86 are provided on both sides of the IDT electrode 84 in the acoustic wave propagation direction. In FIG. 12, the outer periphery of the space portion 9 is indicated by a dashed line. Here, the IDT electrode 84 has a first busbar 84a, a second busbar 84b,electrodes 84c as a plurality of first electrode fingers, and electrodes 84d as a plurality of second electrode fingers. The plurality of electrodes 84c are connected to the first busbar 84a. The plurality of electrodes 84d are connected to the second busbar 84b. The plurality of electrodes 84c and the plurality of electrodes 84d are interdigitated with each other.

In the acoustic wave device 81, a Lamb wave as a plate wave is excited by applying an AC electric field to the IDT electrode 84 above the space portion 9. Since the reflectors 85 and 86 are provided on both sides, resonance characteristics due to the Lamb wave can be obtained.

As described above, an acoustic wave device according to an example embodiment of the present disclosure may use a plate wave.

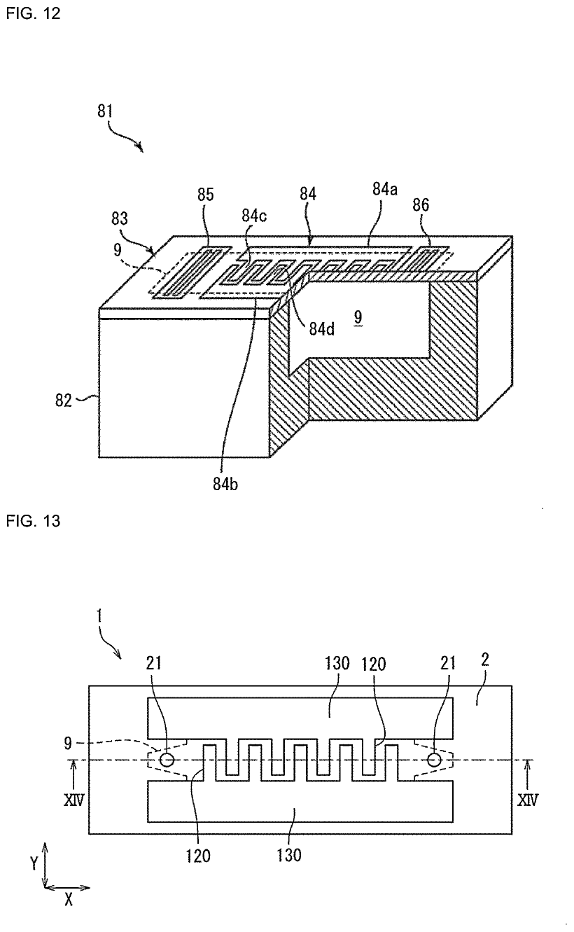

With reference to FIGS. 13 to 22, an acoustic wave device 1 according to an example embodiment of the present disclosure will be described. In this example embodiment, the description of contents that overlap the acoustic wave devices of the first to fourth aspects will be omitted as appropriate. Hereinafter, the description of the acoustic wave devices of the first to fourth aspects can be applied.

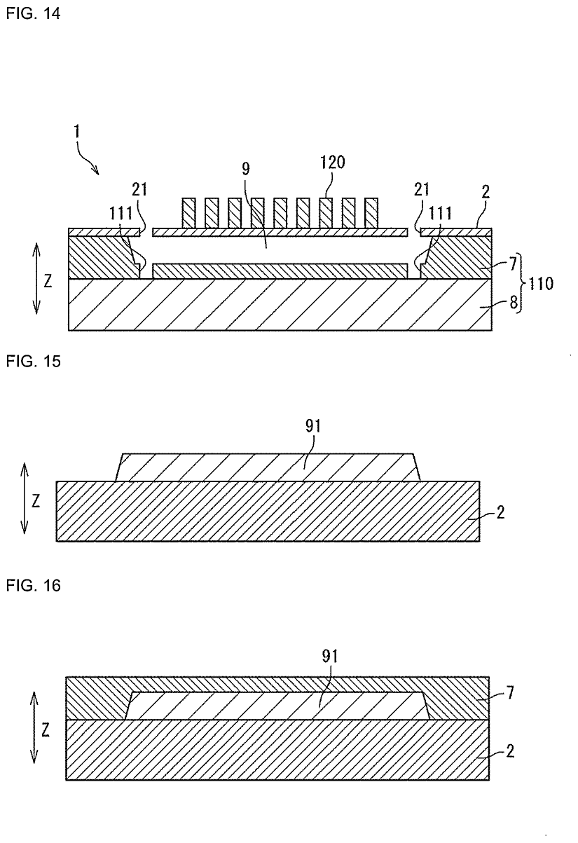

As illustrated in FIGS. 13 and 14, the acoustic wave device 1 includes a support substrate 110, a piezoelectric layer 2, and a functional electrode 120. The support substrate 110 includes a support 8 and an insulating layer (an example of an intermediate layer) 7 provided on the support 8. The piezoelectric layer 2 is provided on the insulating layer 7 in a lamination direction Z of the support 8, the insulating layer 7, and the piezoelectric layer 2. The piezoelectric layer 2 has a through-hole 21 extending through the piezoelectric layer 2 in the lamination direction Z. The functional electrode 120 is provided on the piezoelectric layer 2 in the lamination direction Z. The functional electrode 120 is located between two wiring electrodes 130 provided on the piezoelectric layer 2 and arranged so as to be spaced apart in a direction (for example, Y direction) intersecting the lamination direction Z.

In this example embodiment, the functional electrode 120 is an IDT electrode including a plurality of electrode fingers. The plurality of electrode fingers of the functional electrode 120 each extend in the Y direction and are spaced apart in the X direction. Each electrode finger of the functional electrode 120 is connected to one of the two wiring electrodes 130.

As illustrated in FIG. 14, the support substrate 110 includes a space portion 9 and a recess 111. The space portion 9 is provided at a position (see FIG. 13) overlapping a portion of the functional electrode 120 in the lamination direction Z. The recess 111 is provided at a position in the space portion 9 at least partially overlapping the through-hole 21 in the lamination direction Z, and is recessed in a direction separating from the piezoelectric layer 2 in the lamination direction Z. In other words, the support substrate 110 includes the space portion 9, and the space portion 9 includes the recess 111 recessed so as to extend from the space portion 9 toward the support 8 in the lamination direction Z. In this example embodiment, the space portion 9 is provided in the insulating layer 7 and is located in the insulating layer 7. The recess 111 is recessed to the support 8 and exposes the surface of the support 8.

With reference to FIGS. 15 to 21, description will be given of an example of a method for manufacturing the acoustic wave device 1 according to the present disclosure.

As illustrated in FIG. 15, a sacrificial layer 91 is formed on the piezoelectric layer 2. The sacrificial layer 91 is formed, for example, by depositing a sacrificial layer material on the entire surface of the piezoelectric layer 2, followed by resist patterning of the surface, and then etching the exposed sacrificial layer and removing the resist.

As illustrated in FIG. 16, the insulating layer 7 is formed on the piezoelectric layer 2 on which the sacrificial layer 91 is formed, and the insulating layer 7 is flattened by grinding. The sacrificial layer 91 is thus embedded in the insulating layer 7.

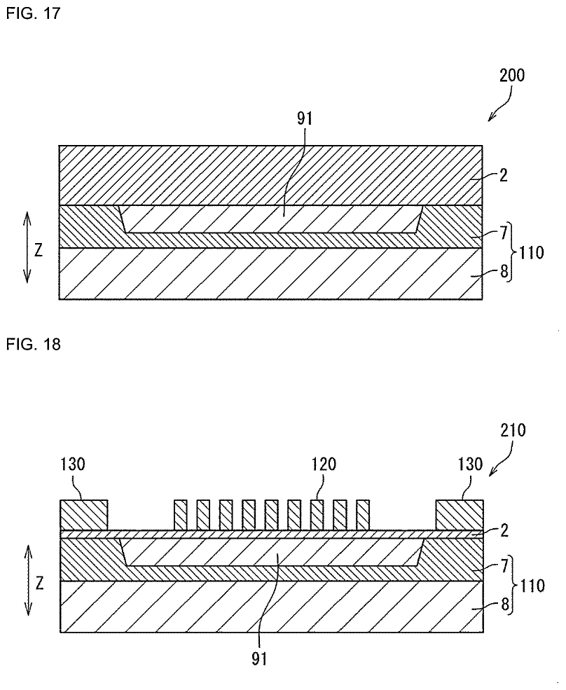

As illustrated in FIG. 17, the support 8 is bonded to the insulating layer 7 having the sacrificial layer 91 embedded therein to form a laminate member 200.

As illustrated in FIG. 18, the piezoelectric layer 2 of the laminate member 200 is thinned by grinding, and the functional electrode 120 and the wiring electrode 130 are formed on the thinned piezoelectric layer 2 by liftoff, thus forming a laminate member 210.

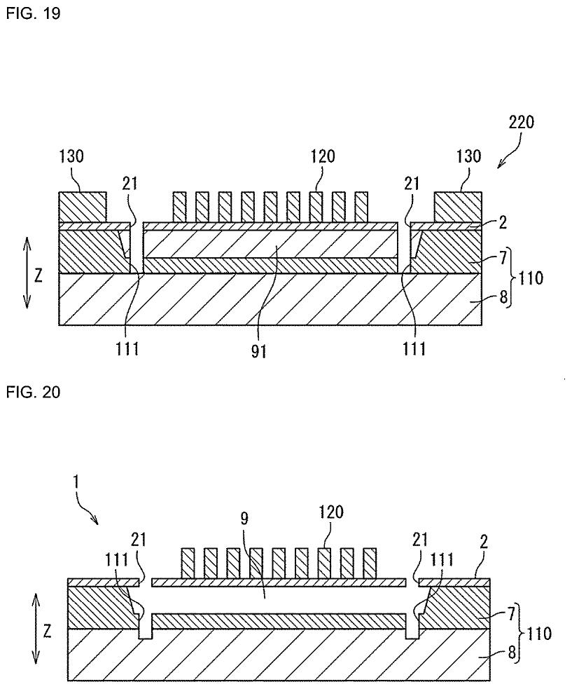

As illustrated in FIG. 19, the through-hole 21 is formed in the piezoelectric layer 2 of the laminate member 210, and the recess 111 is formed in the insulating layer 7, thus forming a laminate member 220. The through-hole 21 is formed so as to extend in the lamination direction Z through the sacrificial layer 91 surrounded by the piezoelectric layer 2 and the support substrate 110 (the insulating layer 7 as an example in this example embodiment). The through-hole 21 and the recess 111 are formed, for example, by resist patterning, dry etching of the piezoelectric layer 2, the sacrificial layer 91, and the insulating layer 7, and then resist removal.

As illustrated in FIG. 14, the sacrificial layer 91 is removed through the through-hole 21 to form a space portion 9 in the laminate member 220, thus forming the acoustic wave device 1. The space portion 9 is formed by removing the sacrificial layer 91 by resist patterning, etching, and resist removal. By forming the space portion 9, a membrane portion is formed in the piezoelectric layer 2. The membrane portion defines, for example, a portion of the piezoelectric layer 2 at least partially overlapping the space portion 9 in the lamination direction Z. In the membrane portion, the functional electrode 120 is located and an excitation region is formed.

As described above, in the acoustic wave device 1 according to the present disclosure, the configuration described above allows an etchant to reach the bottom surface of the sacrificial layer 91 from the start of etching when removing the sacrificial layer 91 to form the space portion 9. This makes it possible to efficiently remove the sacrificial layer 91. As a result, the manufacturing cost of the acoustic wave device 1 can be reduced.

In an acoustic wave device 100 (see FIG. 22) having no recess 111, when heat treatment such as reflow is performed for substrate mounting, a crack 300 may occur in the insulating layer 7 at a position at least partially overlapping a sacrificial layer removal opening hole 121 in the lamination direction Z. In the acoustic wave device 1 according to an example embodiment of the present disclosure, the configuration described above reduces or prevents the crack 300 at a position in the insulating layer 7 at least partially overlapping the through-hole 21.

The acoustic wave device 1 can also be configured as follows.

The recess 111 is not limited to being recessed to the surface of the support 8, and may be recessed into the support 8, as illustrated in FIG. 20, for example.

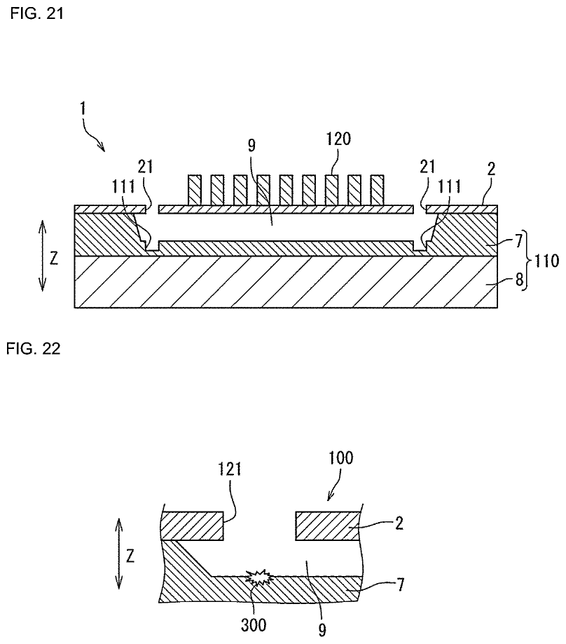

The bottom surface of the recess 111 is not limited to reaching the support 8, and does not have to reach the support 8, as illustrated in FIG. 21, for example. That is, the surface of the support 8 does not have to be exposed from the bottom surface of the recess 111. The recess 111 in FIG. 21 is recessed to a position in the insulating layer 7 on the piezoelectric layer 2 side with respect to the support 8, and has its bottom surface defined by the insulating layer 7.

The space portion 9 is not limited to being located in the insulating layer 7, and may be located across the insulating layer 7 and the support 8, for example.

At least a portion of the configuration of the acoustic wave device 1 of the present disclosure may be added to the acoustic wave devices of the first to fourth aspects of example embodiments of the present disclosure, or at least a portion of the configuration of the acoustic wave devices of the first to fourth aspects of example embodiments of the present disclosure may be added to the acoustic wave device 1 of the present disclosure.

Various example embodiments of the present disclosure have been described in detail above with reference to the drawings.

Any of the various example embodiments or modifications may be appropriately combined to achieve the effects thereof. In addition, combinations of example embodiments, combination of examples, or combinations of example embodiments and examples is possible, or combinations of features of different example embodiments or examples are also possible.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate including a support and an intermediate layer on the support;
a piezoelectric body layer on the intermediate layer; and
a functional electrode on the piezoelectric body layer; wherein
the piezoelectric body layer includes:
a through-hole extending through the piezoelectric body layer in a lamination direction of the support, the intermediate layer, and the piezoelectric body layer; and
the support substrate includes:
a space portion at a position overlapping a portion of the functional electrode in the lamination direction; and
a recess at a position in the space portion at least partially overlapping the through-hole in the lamination direction, the recess being recessed in a direction separating from the piezoelectric body layer.

2. The acoustic wave device according to claim 1, wherein the space portion is located in the intermediate layer.

3. The acoustic wave device according to claim 1, wherein the space portion extends across the intermediate layer and the support.

4. The acoustic wave device according to claim 1, wherein the recess is recessed to the support.

5. The acoustic wave device according to claim 4, wherein the recess is recessed into the support.

6. The acoustic wave device according to claim 1, wherein the recess is recessed to a position in the intermediate layer on the piezoelectric body layer side with respect to the support.

7. The acoustic wave device according to claim 1, wherein the functional electrode is an interdigital transducer electrode.

8. The acoustic wave device according to claim 7, wherein the piezoelectric body layer includes lithium niobate or lithium tantalate;
the interdigital transducer electrode includes a first electrode finger and a second electrode finger facing each other in a direction intersecting the lamination direction;
the first electrode finger and the second electrode finger are adjacent to each other; and
d/p is less than or equal to about 0.5, where d is a thickness of the piezoelectric body layer and p is a center-to-center distance between the first electrode finger and the second electrode finger.

9. The acoustic wave device according to claim 8, wherein d/p is less than or equal to about 0.24.

10. The acoustic wave device according to claim 8, wherein, MR≤about 1.75(d/p)+0.075 is satisfied, where MR is a metallization ratio that is a ratio of an area of the first electrode finger and the second electrode finger in an excitation region to the excitation region, the excitation region being a region where the first electrode finger and the second electrode finger overlap in the direction intersecting the lamination direction.

11. The acoustic wave device according to claim 8, wherein
Euler angles (φ, θ, ψ) of the lithium niobate or lithium tantalate are within a range of Expression (1), Expression (2), or Expression (3):
(0°±10°, 0° to 20°, any ψ) Expression (1)
(0°±10°, 20° to 80°, 0° to 60° (1−(θ−50)²/900)^{1/2}) or (0°±10°, 20° to 80°, [180°−60°(1−(θ−50)²/900)^{1/2]} to 180°) Expression (2)
(0°±10°, [180°−30°(1−(ψ−90)²/8100)^{1/2]} to 180°, any ψ) Expression (3)

12. The acoustic wave device according to claim 7, wherein
the piezoelectric body layer includes lithium niobate or lithium tantalate; and
the acoustic wave device is structured to use a bulk wave in a thickness-shear mode.

13. The acoustic wave device according to claim 1, wherein the acoustic wave device is structured to use a plate wave.

14. A method for manufacturing an acoustic wave device including a support substrate including a support and an intermediate layer on the support, a piezoelectric body layer on the intermediate layer, and a functional electrode on the piezoelectric body layer, in which the piezoelectric body layer includes a through-hole extending through the piezoelectric body layer in a lamination direction of the support, the intermediate layer, and the piezoelectric body layer, and the support substrate includes a space portion provided at a position overlapping a portion of the functional electrode in the lamination direction, and a recess at a position in the space portion at least partially overlapping the through-hole in the lamination direction, the recess being recessed in a direction separating from the piezoelectric body layer, the method comprising:
forming the through-hole so as to extend through a sacrificial layer surrounded by the piezoelectric body layer and the support substrate in the lamination direction; and
removing the sacrificial layer through the through-hole to form the space portion.

15. The method according to claim 14, wherein the space portion is located in the intermediate layer.

16. The method according to claim 14, wherein the space portion extends across the intermediate layer and the support.

17. The method according to claim 14, wherein the recess is recessed to the support.

18. The method according to claim 14, wherein the recess is recessed into the support.

19. The method according to claim 14, wherein the recess is recessed to a position in the intermediate layer on the piezoelectric body layer side with respect to the support.

20. The method according to claim 14, wherein the functional electrode is an interdigital transducer electrode.
